(19) United States
(12) Patent Application Publication
(10) Pub. No.: US 2025/0048899 A1
(43) Pub. Date: Feb. 6, 2025

(54) DISPLAY PANEL AND DISPLAY DEVICE

(71) Applicant: Hubei Yangtze Industrial Innovation Center of Advanced Display Co., LTD., Wuhan (CN)

(72) Inventor: Yanzi LIU, Wuhan (CN)

(21) Appl. No.: 18/754,474

(22) Filed: Jun. 26, 2024

(30) Foreign Application Priority Data
Jul. 31, 2023 (CN) 202310962403.3

(51) Int. Cl. H10K 59/80; H10K 59/90

(52) U.S. Cl. CPC H10K 59/879; H10K 59/90

(57) ABSTRACT

A display panel includes a display area, a substrate, a light-emitting element, a packaging layer, and a first transparent light guide unit. The display area includes a first display area and a second display area at least partially surrounding the first display area. The first display area is configured with a photosensitive element. Both the first display area and the second display area comprise an opening area and a non-opening area located between adjacent opening areas. The light-emitting element, including an anode, a light-emitting layer, and a cathode, is located on one side of the substrate and in the display area. The packaging layer is located on one side of the light-emitting element away from the substrate and in the non-opening area. The first transparent light guide unit is positioned in the first display area and on one side of the packaging layer away from the substrate.

### CROSS-REFERENCE TO RELATED APPLICATION

This application claims priority to Chinese Patent Application No. 202310962403.3, filed on Jul. 31, 2023, the entire content of which is incorporated herein by reference.

### TECHNICAL FIELD

The present disclosure relates to the field of display technology and, in particular, to a display panel and a display device.

### BACKGROUND

Currently, a display device, including a mobile phone and a tablet, often needs to reserve space on the front side of commonly-used electronic photosensitive apparatuses, such as a front camera, an infrared sensing device, and a fingerprint recognition device. For example, the commonly-used electronic photosensitive apparatuses are positioned at the front top of a display device, forming a non-display area at a corresponding location. This decreases a screen-to-body ratio of the display device.

With the development of display technology, a display panel has an increasingly higher screen-to-body ratio. A full-screen display, offering narrow-border or even borderless display effects, has gained widespread attention. To increase the screen-to-body ratio, an optical component area can be set up in a display area of the display panel to accommodate the commonly-used electronic photosensitive apparatuses. For example, the optical component area can be set up in the display area of a screen, with a camera positioned below the screen and correspondingly set in the optical component area. During normal display, the optical component area can play a display function. When capturing photos or videos is required, the camera takes photos or videos through the optical component area, so that the optical component area can simultaneously realize the display and shooting functions.

A photosensitive performance of the optical component area is closely related to an intensity of light that can be received by a photosensitive apparatus in the optical component area. Enhancing a light sensitivity of the optical component area during a photosensitive phase has become one of pressing technical challenges to be addressed.

### SUMMARY

One aspect of the present disclosure provides a display panel. The display panel has a display area, including a first display area and a second display area at least partially surrounding the first display area. The first display area is configured with a photosensitive element. Both the first display area and the second display area have an opening area and a non-opening area located between adjacent opening areas. The display panel also has a substrate and a light-emitting element. The light-emitting element is located over one side of the substrate and in the display area. The light-emitting element has an anode, a light-emitting layer, and a cathode. Along a first direction, the light-emitting layer is located between the anode and the cathode. The light-emitting layer is located at least in the opening area. The first direction is perpendicular to a plane of substrate. The display panel also has a packaging layer that is located over one side of the light-emitting element away from the substrate. The display panel also has a first transparent light guide unit that is located in the first display area and over one side of the packaging layer away from the substrate. The first transparent light guide unit is only located in the non-opening area. The display panel includes a photosensitive phase. During the photosensitive phase, the first transparent light guide unit is used to guide external light to the photosensitive element.

Another aspect of the present disclosure provides a display device. The display device has a display panel. The display panel has a display area, including a first display area and a second display area at least partially surrounding the first display area. The first display area is configured with a photosensitive element. Both the first display area and the second display area have an opening area and a non-opening area located between adjacent opening areas. The display panel also has a substrate and a light-emitting element. The light-emitting element is located over one side of the substrate and in the display area. The light-emitting element has an anode, a light-emitting layer, and a cathode. Along a first direction, the light-emitting layer is located between the anode and the cathode. The light-emitting layer is located at least in the opening area. The first direction is perpendicular to a plane of substrate. The display panel also has a packaging layer that is located over one side of the light-emitting element away from the substrate. The display panel also has a first transparent light guide unit that is located in the first display area and over one side of the packaging layer away from the substrate. The first transparent light guide unit is only located in the non-opening area. The display panel includes a photosensitive phase. During the photosensitive phase, the first transparent light guide unit is used to guide external light to the photosensitive element.

### BRIEF DESCRIPTION OF THE DRAWINGS

The accompanying drawings, which are incorporated in and constitute a part of this specification, illustrate embodiments of the present disclosure and together with the description, serve to explain the principles of the present disclosure.

FIG. 1 illustrates a top view of the display panel according to embodiments of the present disclosure.

FIG. 2 illustrates a cross-sectional view of the display panel along the AA direction in FIG. 1.

FIG. 3 illustrates another cross-sectional view of the display panel along the AA direction in FIG. 1.

FIG. 4 illustrates a schematic diagram of an optical path corresponding to the flat layer, the first transparent light guide unit, and the packaging layer in FIG. 3.

FIG. 5 illustrates another cross-sectional view of the display panel along the AA direction in FIG. 1.

FIG. 6 illustrates a schematic diagram of an optical path corresponding to the flat layer, the first transparent light guide unit, and the packaging layer in FIG. 5.

FIG. 7 illustrates another cross-sectional view of the display panel along the AA direction in FIG. 1.

FIG. 8 illustrates a schematic diagram of the distribution of a first transparent light guide unit in the first display area.

FIG. 9 illustrates a relative positional relationship diagram of the first transparent light guide unit and its adjacent opening area.

FIG. 10 illustrates another cross-sectional view of the display panel along the AA direction in FIG. 1.

FIG. 11 illustrates another cross-sectional view of the display panel along the AA direction in FIG. 1.

FIG. 12 illustrates another cross-sectional view of the display panel along the AA direction in FIG. 1.

FIG. 13 illustrates another cross-sectional view of the display panel along the AA direction in FIG. 1.

FIG. 14 illustrates another cross-sectional view of the display panel along the AA direction in FIG. 1.

FIG. 15 illustrates another cross-sectional view of the display panel along the AA direction in FIG. 1.

FIG. 16 illustrates a top view of a second transparent light guide unit and a corresponding light-emitting element.

FIG. 17 illustrates a top view of a display device according to embodiments of the present disclosure.

### DETAILED DESCRIPTION OF THE EMBODIMENTS

Embodiments of the present disclosure are described in detail with reference to the accompanying drawings. It should be noted that the relative arrangement of components and steps, numerical expressions, and numerical values set forth in these examples do not limit the scope of the disclosure unless otherwise specifically stated.

The following description of embodiments of the present disclosure is merely illustrative in nature and is in no way intended to limit the scope of the present disclosure and the application or the use of the present disclosure.

Techniques, methods, and devices known to those persons of ordinary skill in the art may not be discussed in detail, but where appropriate, the techniques, methods and devices should be considered a part of the specification.

In all examples presented and discussed in the present disclosure, specific values are to be construed as illustrative only rather than limiting. Accordingly, other examples of the exemplary embodiments may have different values.

It will be apparent to those persons of ordinary skill in the art that various modifications and variations can be made in the present disclosure without departing from the spirit or scope of the invention. Thus, the present disclosure intends to cover the scope of the modifications and variations of the present disclosure corresponding to the claims (claimed technical approaches) and their equivalents. It should be noted that the implementations provided by embodiments of the present disclosure can be combined with each other if there is no contradiction.

It should be noted that similar reference numbers and letters refer to similar items in the following figures, so that once an item is defined in one figure, it does not require further discussion in subsequent figures.

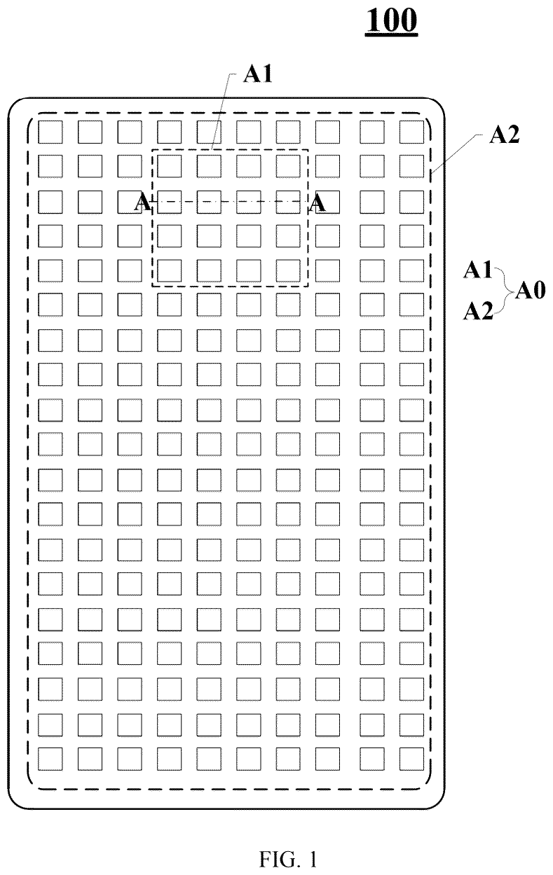

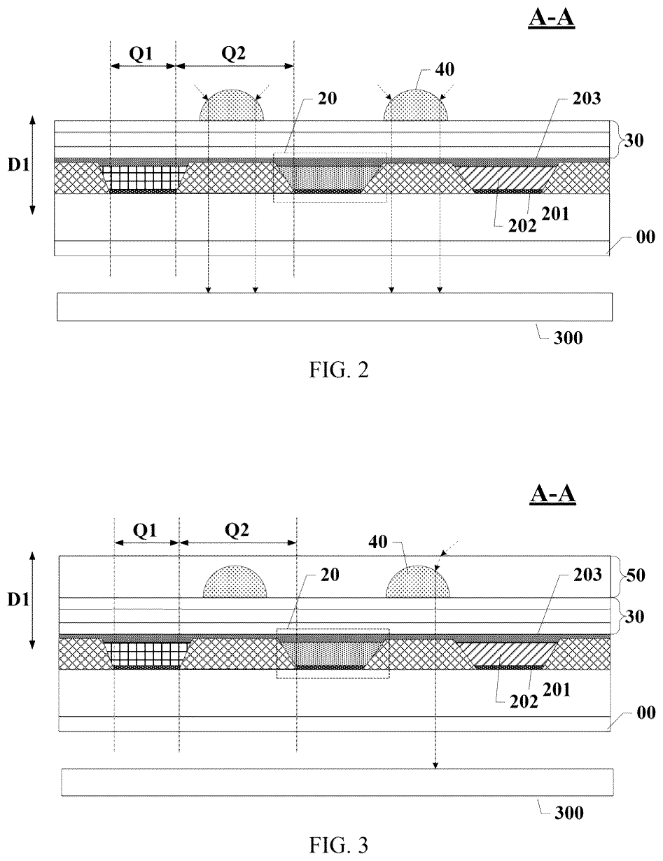

FIG. 1 is a top view of a display panel according to embodiments of the present disclosure. FIG. 2 shows a cross-sectional view of the display panel along the AA direction in FIG. 1. As shown in FIG. 1 and FIG. 2, the present disclosure provides a display panel 100, including a display area A0. The display area A0 includes a first display area A1 and a second display area A2 at least partially surrounding the first display area A1. The first display area A1 is used to accommodate a photosensitive element 300. Both the first display area A1 and the second display area A2 have an opening area Q1 and a non-opening area Q2 disposed between adjacent opening areas Q1.

The display panel 100 includes a substrate 00 and a light-emitting element 20. The light-emitting element 20 is located over one side of the substrate 00 and in the display area A0. The light-emitting element 20 includes an anode 201, a light-emitting layer 202, and a cathode 203. Along a first direction D1, the light-emitting layer 202 is located between the anode 201 and the cathode 203. Moreover, the light-emitting layer 202 is at least located in the opening area Q1. A first direction D1 is perpendicular to the plane of the substrate 00.

The display panel 100 also includes a packing layer 30 over one side of the light-emitting element 20 away from the substrate 00. The display panel 100 further includes a first transparent light guide unit 40, located in the first display area A1 and over one side of the packaging layer 30 away from the substrate 00. The first transparent light guide unit 40 is only located in the non-opening area Q2. The display panel includes a photosensitive phase. During the photosensitive phase, the first transparent light guide unit 40 is used to conduct external light to the photosensitive element 300.

It should be noted that FIG. 1 only exemplarily illustrates the display panel of the present disclosure using a rounded rectangular display panel. FIG. 1 does not limit the specific structure of the display panel of the present disclosure. In some embodiments, the shape of the display panel can also be a rectangle, a circle, an ellipse, or other structures including an arc edge, which is not specifically limited by the present disclosure. FIG. 1 only illustrates a relative position of the first display area A1 on the display panel. In some embodiments, the first display area A1 can also be disposed at other positions on the display panel. The shape of the first display area A1 can be adjusted according to specific requirements. The square in FIG. 1 is only for illustration. For example, the first display area A1 can also be configured as a circle, racetrack shape, etc. In addition, the size of the first display area A1 can also be flexibly adjusted according to actual needs. The pixel arrangement in FIG. 1 is only for demonstration and does not limit the number and arrangement of sub-pixels in the first display area A1 and the second display area A2 of the display panel. FIG. 2 only illustrates the relative positioning of some of the light-emitting elements 20 and the first transparent light guide units 40 in the first display area A1 of the display panel. FIG. 2 does not restrict the actual number of layers of film and the actual dimension of each film layer included in the display panel.

Specifically, the display panel 100 provided by embodiments of the present disclosure is configured with the first display area A1 and the second display area A2. Optionally, FIG. 1 exemplarily shows the second display area A2 surrounds the first display area A1. In some embodiments, the second display area A2 can also partially surround the first display area A1, which is not limited by the present disclosure. Optionally, the first display area A1 is used to accommodate the photosensitive element 300, including a camera, an infrared sensing device, a fingerprint recognition device, etc. The light-emitting element 20 is configured in both the first display area A1 and the second display area A2. During the display phase, the light-emitting element 20 in the second display area A2 and the first display area A1 performs display functions. During the photosensitive phase, the first display area A1 serves as a light-transmitting area to realize a photosensitive function, while the light-emitting element 20 of the first display area A1 does not emit light. For example, when the first display area A1 is equipped with a camera, during the photosensitive phase, the first display area A1 serves as a light-transmitting area to implement a picture shooting function. The first display area A1 that exerts the photosensitive function is integrated into the display area A0, which facilitates reducing the space of the non-display area A0 of the display panel, realizing a narrow frame design or a frameless design of the display panel, and improving the overall screen-to-body ratio of the display panel.

The light-emitting element 20 in embodiments of the present disclosure includes the anode 201, the light-emitting layer 202, and the cathode 203. The light-emitting layer 202 is located in a pixel opening defined by a pixel definition layer. Generally, an area where the pixel opening overlaps with the anode 201 can be considered as the opening area Q1 of the display panel. The non-opening area Q2 can be considered as an area between two adjacent opening areas Q1. The packaging layer 30 is configured on the side of the light-emitting element 20 away from the substrate 00. The packaging layer 30 is used to package the light-emitting element 20 to prevent external moisture and oxygen from corroding the light-emitting element 20 and affecting the normal performance of the light-emitting element 20. Thus, it is advantageous for improving the light-emitting reliability of the light-emitting element 20.

When the first display area A1 is introduced to the display area A0 to accommodate the photosensitive element 300, for example, a camera, an infrared sensing device, and a fingerprint identification device, during the photosensitive phase, the photosensitive performance of the photosensitive element 300 is closely related to the amount of light it senses. Generally, the greater the amount of light that the photosensitive element 300 senses during the photosensitive phase, the more favorable it is for improving its photosensitive performance. However, external light transmitted to the photosensitive element 300 during the photosensitive phase is limited, thus affecting the photosensitive performance of the display panel.

To address this, embodiments of the present disclosure introduce the first transparent light guide unit 40 into the first display area A1 of the display panel. The first transparent light guide unit 40 is positioned in the non-opening area Q2 to avoid affecting the amount of light emitted by the light-emitting element 20 located in the opening area Q1. During the photosensitive phase, the first transparent light guide unit 40 located in the non-opening area Q2 can conduct external light to the photosensitive element 300 in the first display area A1. With the light-conducting function of the first transparent light guide unit 40, the amount of light transmitted to the photosensitive element 300 is effectively increased. Compared to products without the first transparent light guide unit 40, the amount of light sensed by the photosensitive element 300 during the photosensitive phase is effectively increased, thereby improving the photosensitivity performance of the display panel.

Optionally, when the first transparent light guide unit 40 is provided in the first display area A1, the first transparent light guide unit 40 may be provided in the non-opening area Q2 between every two adjacent light-emitting elements 20. Thus, the amount of light transmitted to the photosensitive element 300 through the first transparent light guide unit 40 is increased during the photosensitive phase, further improving the photosensitive performance of the display panel.

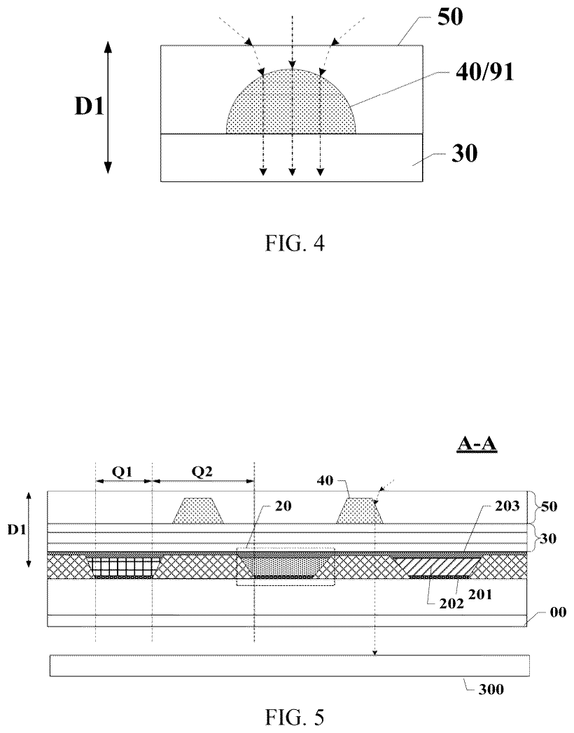

FIG. 3 shows another AA cross-sectional view of the display panel in FIG. 1. FIG. 4 shows a schematic diagram of an optical path corresponding to a flat layer 50, the first transparent light guide unit 40, and the packaging layer 30 in FIG. 3. Embodiments of the present disclosure show a scheme of forming the flat layer 50 on one side of the first transparent light guide unit 40 away from the substrate 00.

As shown in FIG. 3 and FIG. 4, in embodiments of the present disclosure, the display panel further includes the flat layer 50. The flat layer 50 is located over the side of the first transparent light guide unit 40 away from the substrate 00. The flat layer 50 is disposed in the first display area A1 and the second display area A2 and covering the first transparent light guide unit 40. A refractive index of the flat layer 50 is N1 and a refractive index of the first transparent light guide unit 40 is N2. A refractive index of the packaging layer 30 contacting the first transparent light guide unit 40 is N3. N1<N2<N3.

Specifically, when the flat layer 50 is introduced into the display panel, the flat layer 50 covers the first transparent light guide unit 40. The first transparent light guide unit 40 is covered by the flat layer 50. A surface of the flat layer 50 facing away from the first transparent light guide unit 40 is a flat surface. Along the first direction D1, the flat layer 50 and the packaging layer 30 are respectively located on both sides of the first transparent light guide unit 40. Embodiments of the present disclosure define the refractive index of the flat layer 50, the refractive index of the first transparent light guide unit 40, and the refractive index of the packaging layer 30 in contact with the first transparent light guide unit 40 in an increasing trend. When an external light is emitted from the flat layer 50 to the first transparent light guide unit 40 and further emitted from the first transparent light guide unit 40 to the packaging layer 30 in contact with the first transparent light guide unit 40, the refraction angle tends to decrease. This transmits a large-viewing-angle light in the external light to the photosensitive element 300. If the first transparent light guide unit 40 is not provided in the display panel, only a small-viewing-angle light may be transmitted to the photosensitive element 300, while the large-viewing-angle light will not be transmitted to the photosensitive element 300. With the introduction of the first transparent light guide unit 40 and the flat layer 50 in the present disclosure, the refractive index of the flat layer 50, the refractive index of the first transparent light guide unit 40, and the refractive index of the packaging layer 30 in contact with the first transparent light guide unit 40 is differentially designed. This makes the large-viewing-angle light is redirected to the photosensitive element 300 by changing an optical path, after passing through the flat layer 50, the first transparent light guide unit 40, and the packaging layer 30. This effectively increases the amount of light received by the photosensitive element 300, thereby further improving the photosensitive performance of the display panel.

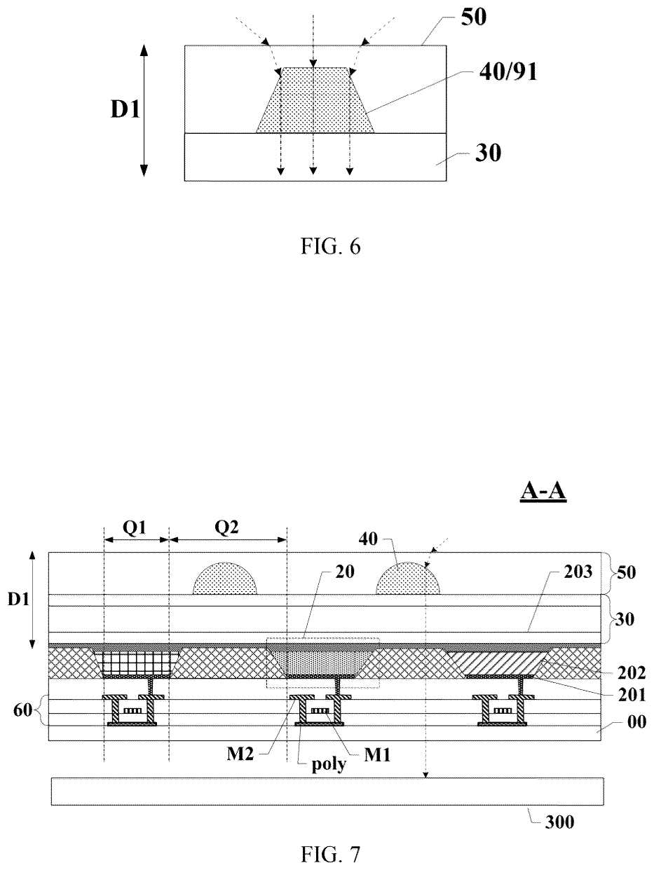

FIG. 5 shows another AA cross-sectional view of the display panel in FIG. 1, and FIG. 6 shows a schematic diagram of an optical path corresponding to the flat layer 50, the first transparent light guide unit 40, and the packaging layer 30 in FIG. 5.

Please refer to FIG. 3 and FIG. 4 as well as FIGS. 5 and 6, in some embodiments, the first transparent light guide unit 40 includes a first microprism 91. The first microprism 91 has a semicircular or trapezoidal first cross-section which is parallel to the first direction D1.

Specifically, embodiments shown in FIG. 3 and FIG. 4 illustrate that the first microprism 91 corresponding to the first transparent light guide unit 40 has a spherical structure and a semicircular cross-section. Embodiments shown in FIG. 5 and FIG. 6 illustrate that the first microprism 91 corresponding to the first transparent light guide unit 40 has a prism structure and a trapezoidal cross-section. When the above two structures are used to form a first microlen, it is beneficial to transmitting the large-viewing-angle light to the photosensitive element 300 during the photosensitive phase, thereby improving the overall photosensitive performance of the display panel.

Optionally, the first microprism 91 can be made of transparent optical glue such as OC glue, and can be formed into a corresponding shape using a Photo process.

FIG. 7 shows another AA cross-sectional view of the display panel in FIG. 1. Some embodiments show a scheme of an array layer 60 in the first display area A1.

As shown in FIG. 7, in some embodiments, the display panel further includes the array layer 60. The array layer 60 is located between the substrate 00 and the light-emitting element 20. The array layer 60 includes a metal structure. Along the first direction D1, the first transparent light guide unit 40 does not overlap with the metal structure.

Specifically, the metal structure in the array layer 60 may include, for example, a metal trace, or a gate electrode of transistor, a source electrode of transistor, a drain electrode of transistor, and so on. Optionally, the array layer 60 includes a first metal layer M1, a second metal layer M2, and a semiconductor layer poly. The first metal layer M1 can be a gate metal layer, and gate electrodes of some transistors in the display panel can be disposed on the first metal layer M1. Source electrodes and drain electrodes of some transistors in the display panel may be located on the second metal layer M2. The semiconductor layer poly includes a source region and a drain region, formed by doping with N-type impurity ions or P-type impurity ions. The source electrode of transistor is electrically connected to the source region of the semiconductor layer through a contact hole, and the drain electrode of transistor is electrically connected to the drain region of the semiconductor layer through the contact hole. It should be noted that FIG. 7 exemplarily shows that the array layer 60 includes one type of transistor, but does not limit the number of types of transistors actually included in the array layer 60. In some embodiments, the array layer 60 may also include two types of transistors. FIG. 7 only illustrates one film layer structure of the array layer 60 and does not limit the number and size of the film layer actually included in the array layer 60.

As shown in FIG. 1 and FIG. 7, since the first display area A1 is used to dispose the photosensitive element 300, all signal traces originally located in the first display area A1 can be disposed as transparent wiring to improve the transmittance of the first display area A1. In some embodiments, at least some of the transistors originally located in the first display area A1 can also be transferred to the second display area A2. FIG. 7 illustrates a scheme where some transistors are retained with the anode 201 of the light-emitting element 20. Of course, in some embodiments, all transistors in the first display area A1 can also be transferred to the second display area A2 to effectively improve the transmittance of the first display area A1. In some embodiments, it is specified that the first transparent light guide unit 40 does not overlap with the metal structure along the first direction D1. In this way, during the photosensitive phase, there will be no metal structure causing reflection in the path through which light is guided to the photosensitive element 300 via the first transparent light guide unit 40. This helps to prevent a reduction in the amount of light transmitted to the photosensitive element 300 due to reflection from the metal structure, thereby ensuring an adequate amount of light is conveyed to the photosensitive element 300.

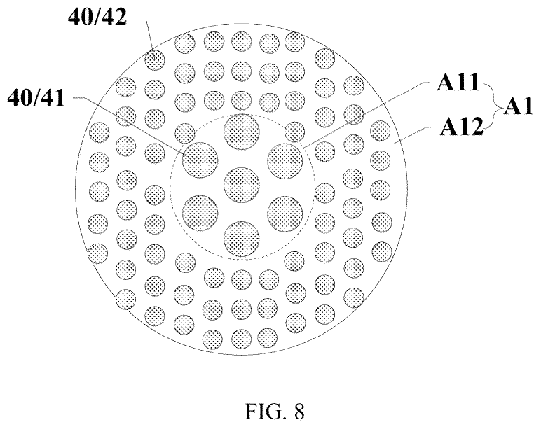

Please appropriately refer to FIG. 1 and FIG. 8, in some embodiments, the first display area A1 includes a first area A11 and a second area A12 surrounding the first area A11. The second area A12 is located between the area A11 and the second display area A2. The first transparent light guide unit 40 includes a first light guide unit 41 located in the first area A11 and a second light guide unit 42 located in the second area A12.

Along the first direction D1, a projected area of a single first transparent light guide unit 40 on the plane of the substrate 00 is S1. A projected area of a single second light guide unit 42 on the plane of the substrate 00 is S2, where S1>S2.

FIG. 8 shows a schematic distribution diagram of the first transparent light guide unit 40 in the first display area A1. As shown in FIG. 8, in an optional implementation of the present disclosure, the first display area A1 includes the first area A11 and the second area A12 surrounding the first area A11. The second area A12 is located between the first area A11 and the second display area A2. The first transparent light guide unit 40 includes the first light guide unit 41 located in the first area A11 and the second light guide unit 42 located in the second area A12. An arrangement density of the second light guide unit 42 is greater than an arrangement density of the first light guide unit 41.

It should be noted that FIG. 8 only illustrates the first transparent light guide unit 40 in the first display area A1, and does not depict other structures in the first display area A1. FIG. 8 exemplarily uses the first display area A1 as a circle, and does not limit the actual shape of the first display area A1. In some embodiments, the first display area A1 may also be non-circular shapes, such as the rectangle shown in FIG. 1, and so on. The first area A11 of the first display area A1 mentioned in some embodiments can be regarded as a central area of the first display area A1. The second area A12 of the first display area A1 can be regarded as a peripheral area A12 of the first display area A1. When the photosensitive element 300 is arranged at a corresponding position of the first display area A1, the orthographic projection of the photosensitive element 300 to the light-exiting surface of the display panel is located in the central area of the first display area A1. In the display panel, metal traces provided in the central area of the first display area A1 (the first area A11) are relatively sparse, while metal traces provided in the second area A12 are relatively dense. As a result, a transmittance of the second area A12 is lower than a transmittance of the first area A11. Therefore, embodiments of the present disclosure perform differentiated designs on the arrangement density of the first light guide unit 41 located in the first area A11 and the arrangement density of the second light guide unit 42 located in the second area A12 to increase the arrangement density of the second light guide unit 42. For example, by reducing the size of the second light guide unit 42 (making it smaller than the size of the first light guide unit 41) and increasing the number of the second light guide units 42, a number of second light guide units 42 in a same area of space is increased and greater than a number of first light guide units 41 in the same area of space. Thus, more densely arranged second light guide units 42 in the same area of space can transmit a larger amount of light from the second area A12 to the photosensitive element 300. This improvement helps to address the issue of low light transmission from the second area A12 to the photosensitive element 300 during the photosensitive phase due to the lower transmittance of the second area A12, thereby enhancing the uniformity of light transmission to the photosensitive element 300 from both the first area A11 and the second area A12.

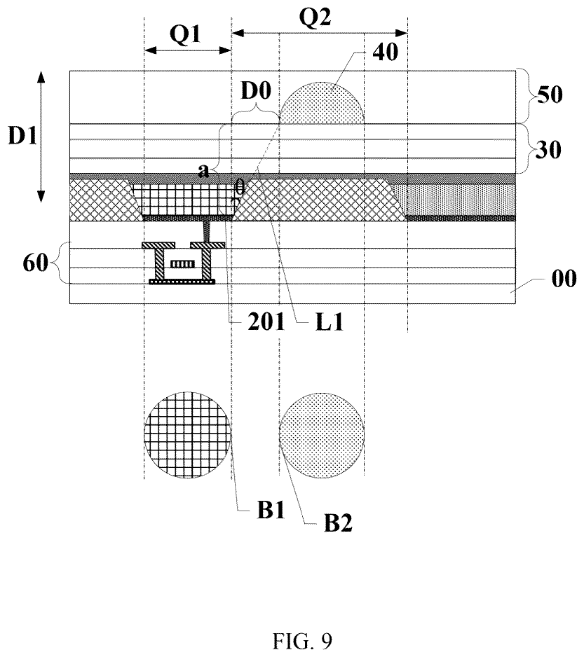

FIG. 9 is a relative positional relationship diagram of the first transparent light guide unit 40 and an opening area Q1 adjacent to the first transparent light guide unit 40. As shown in FIG. 9, in some embodiments, there is a first interval between an orthographic projection of the first transparent light guide unit 40 in a substrate 00 plane and the opening area Q1 adjacent to the first transparent light guide unit 40. The minimum width of the first interval is D0. D0=a×tan θ, where ‘a’ is a distance along the first direction D1 between one surface of the first transparent light guide unit 40 facing the substrate 00 and one surface of the light-emitting layer 202 facing the anode 201. An edge of the opening area Q1 facing its adjacent first transparent light guide unit 40 is a first edge B1. An edge of the transparent light guide unit 40 facing its adjacent opening area Q1 is a second edge B2. A line connecting the first edge B1 and the second edge B2 is a first line segment L1. θ is an acute angle between a straight line where the first line segment L1 is located and the substrate 00 plane, where 15°≤θ≤30°.

Specifically, when the first transparent light guide unit 40 is disposed in the non-opening area Q2, embodiments of the present disclosure further define a minimum width of the first interval between the orthogonal projection of the first transparent light guide unit 40 on the substrate 00 and the opening area Q1. Considering that in the large-viewing-angle light emitted by the light emitting element 20, there is generally a requirement for a viewing angle of 60°˜75°, meaning that when the first transparent light guide unit 40 is disposed in the non-opening area Q2, the first transparent light guide unit 40 cannot block the large-viewing-angle light from the light-emitting element 20 between 60° to 75°. Assume that the shortest line segment between the first edge B1 of the opening area Q1 and the second edge B2 of the first transparent light guide unit 40 is the first line segment L1. When the acute angle θ between the first line segment L1 and the substrate 00 plane is 15° to 30°, it can prevent the large-viewing-angle light of an angle between 60° to 75° emitted by the light-emitting element 20 being blocked or affected by the first transparent light guide unit 40. At this time, it is only necessary to set the minimum width of the first interval between the first transparent light guide unit 40 and the opening area Q1 to D0=a×tan θ, which helps ensure the stability and reliability of the large-viewing-angle light emission from the light-emitting element 20.

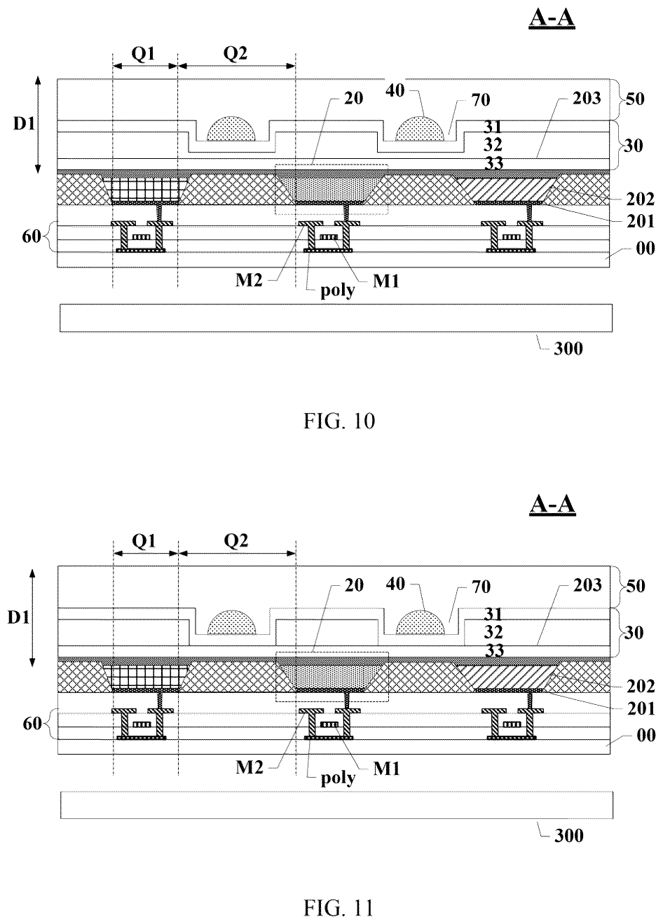

FIG. 10 shows another AA cross-sectional view of the display panel in FIG. 1. As shown in FIG. 10, in some embodiments, the packaging layer 30 includes a plurality of grooves 70. A groove 70 is located in the non-opening area Q2. The first transparent light guide unit 40 is located in the groove 70.

Specifically, embodiments of the present disclosure illustrate a scheme of forming the groove 70 on one surface of the packaging layer 30 facing the flat layer 50. When the groove 70 are formed on the surface of the flat layer 50, a thickness of the portion of the packaging layer 30 provided with the groove 70 will become thinner. At this time, when the first transparent light guide unit 40 is placed in the groove 70 and the photosensitive element 300 is placed on the side of the substrate 00 away from the first transparent light guide unit 40, the thickness of the film layer between the light unit 40 and the photosensitive element 300 is reduced and the path for a light to be transmitted from the first transparent light guide unit 40 to the photosensitive element 300 is shortened. Thus, the light loss caused in the process of being transmitted to the photosensitive element 300 from the first transparent light guide unit 40 is reduced, increasing the amount of light transmitted to the photosensitive element 300 and improving the photosensitive performance of the display panel.

It should be noted that the groove 70 in the packaging layer 30 can be regarded as being obtained by removing part of the film layer of the packaging layer 30. Since the groove 70 is located in the non-opening area Q2, it will not affect a packaging effect of the light-emitting element 20 of the opening area Q1.

FIG. 11 shows another AA cross-sectional view of the display panel in FIG. 1. In some embodiments, the packaging layer 30 includes a first inorganic layer 31, an organic layer 32, and a second inorganic layer 33. Along the first direction D1, the organic layer 32 is located between the first inorganic layer 31 and the second inorganic layer 33. The organic layer 32 is at least located in the opening area Q1, and the organic layer 32 does not overlap with the groove 70.

Specifically, both FIG. 10 and FIG. 11 show schemes for forming the groove 70 on the packaging layer 30. The difference is that the groove 70 shown in FIG. 10 is achieved by removing a portion of the organic layer 32 of the packaging layer 30 in the non-opening area Q2. The groove 70 shown in FIG. 11 is realized by removing the entire organic layer 32 in the packaging layer 30 in part of the non-opening area Q2. Thus, the depth of the groove 70 in FIG. 11 will be greater than the depth of the groove 70 in FIG. 10. The first inorganic layer 31 and the second inorganic layer 33 in the packaging layer 30 have good capability of isolating water and oxygen. The organic layer 32 has good elasticity. Therefore, the first inorganic layer 31 and the second inorganic layer 33 play a major role in isolating water and oxygen. When the groove 70 is formed by removing the organic layer 32 in the non-opening area Q2, it will not affect the organic layer 32 in the opening area Q1. At a position corresponding to the light-emitting element 20, the packaging layer 30 still remains a packaging structure in which the first inorganic layer 31, the organic layer 32, and the second inorganic layer 33 are overlappingly arranged. At a position where the groove 70 is present, the organic layer 32 is removed, which represents a packaging structure that the first inorganic layer 31 and the second inorganic layer 33 are directly connected to each other. The way that the first inorganic layer 31 and the second inorganic layer 33 directly connected to each other can also achieve a better packaging effect. Considering that the organic layer 32 has good elasticity and a large thickness, when the groove 70 is formed by removing the organic layer 32, it is equivalent to removing the thicker film layer in the packaging layer 30, which will not affect the packaging effect while effectively increase the depth of the groove 70. Therefore, the distance between the first transparent light guide unit 40 and the photosensitive element 300 is effectively reduced, that is, reducing the path of light transmission from the first transparent light guide unit 40 to the photosensitive element 300, which reduces light loss during light transmission. Thus, it is beneficial to increasing the light sensitivity of the photosensitive element 300.

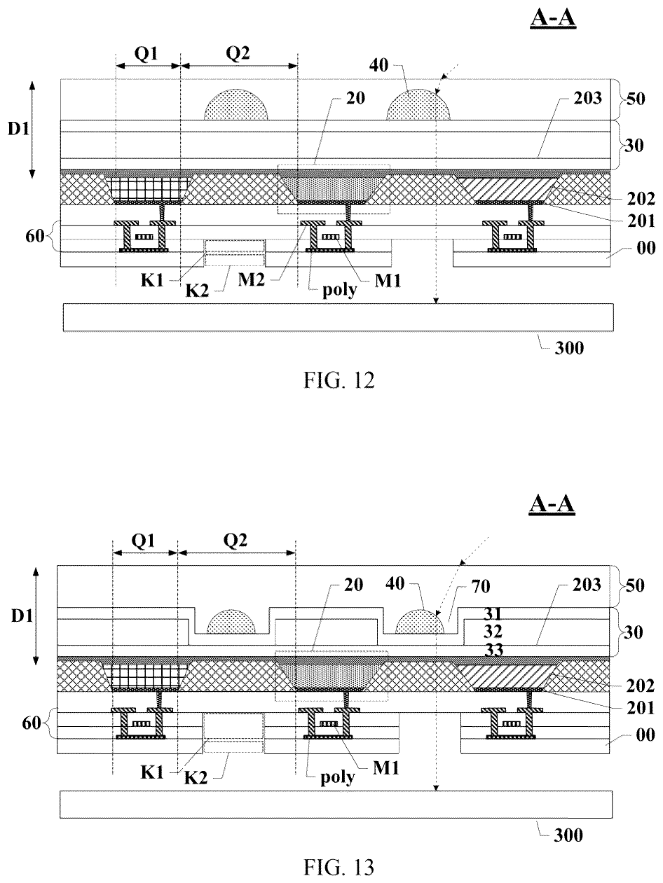

FIG. 12 shows another AA cross-sectional view of the display panel in FIG. 1. In some embodiments, a scheme of thinning a portion of the array layer 60 is shown.

Please refer to FIG. 12. In some embodiments, the display panel further includes an array layer 60. The array layer 60 is located between the substrate 00 and the light-emitting element 20. In the first display area A1, a total thickness of a film layer which is overlapped by the first transparent light guide unit 40 and the array layer 60 along the first direction D1 is smaller than a total thickness of a film layer of the array layer 60 located in the opening area Q1.

Embodiments of the present disclosure show a scheme for differentially designing the thickness of the array layer 60 in the first display area A1. Specifically, the thickness of the film layer of the portion of the array layer 60 in the first display area A1 located in the non-opening area Q2 is reduced to be smaller than the thickness of the portion of film layer located in the opening region Q1. For example, by removing a portion of the insulating layer in the array layer 60, an existing metal layout in the array layer 60 will not be affected. In some embodiments, along the first direction D1, the thinned area of the array layer 60 overlaps with the first transparent light guide unit 40 in the non-opening area Q2. During the photosensitive phase, when external light is emitted to the photosensitive element 300 through the first transparent light guide unit 40, it will pass through the thinned film layer in the array layer 60, which is equivalent to reducing the transmission path of light in the display panel. This facilitates reducing the light loss during the light transmission to the photosensitive element 300, increasing the light sensitivity of the photosensitive element 300, thereby improving the photosensitive performance of the display panel.

FIG. 13 shows another AA cross-sectional view of the display panel in FIG. 1. When the groove 70 is formed in the packaging layer 30, the first transparent light guide unit 40 is disposed in the groove 70, and the array layer 60 located directly below the first transparent light guide unit 40 along the first direction D1 is thinned, it is more beneficial to reduce the path when light is transmitted from the first transparent light guide unit 40 to the photosensitive element 300. The light loss when light is transmitted to the photosensitive element 300 during the photosensitive phase is reduced to increase the light sensitivity of the photosensitive element 300 during the photosensitive phase and improve the overall photosensitive performance of the display panel.

Continuing to refer to FIG. 12 and FIG. 13, in some embodiments, the array layer 60 includes a first light hole K1 located in the non-opening area Q2. Along the first direction D1, the first light hole K1 penetrates at least part of the film layer of the array layer 60, and the first light hole K1 overlaps the first transparent light guide unit 40.

When thinning the portion of the array layer 60 located in the non-opening area Q2 in the first display area A1, a feasible implementation method is to form a light hole in the portion of the array layer 60 located in the non-opening area Q2, that is, a light hole allowing the light emitted from the first transparent light guide unit 40 to pass through to the photosensitive element 300. The light hole can be embodied as a hollow structure. When the light passes through the light hole, it can be regarded as there is no or negligible light loss. The amount of light emitted to the photosensitive element 300 during the photosensitive phase is effectively increased, which is beneficial to improving the photosensitive performance of the display panel. It should be noted that the film layer of the array layer 60 that the first light hole K1 penetrates through is an insulating layer of the array layer 60, avoiding the metal layer on the array layer 60. Therefore, it will not affect the metal layer on the array layer 60.

Continuing to refer to FIG. 12 and FIG. 13, in some embodiments, the substrate 00 includes a second light hole K2 located in the non-opening area Q2. Along the first direction D1, the second light hole K2 penetrates through the substrate 00, and the second light hole K2 overlaps the first transparent light guide unit 40. The photosensitive element 300 is located on one side of the substrate 00 away from the light emitting element 20.

Embodiments of the present disclosure show a scheme of forming the second light hole K2 on the substrate 00. The second light hole K2 is connected to the first light hole K1. Optionally, the first light hole K1 and the second light hole K2 are coaxial and have the same diameter. In this way, the first light hole K1 and the second light hole K2 can be made in a same process, which is beneficial to simplifying a production process of the first light hole K1 and the second light hole K2.

In some embodiments, when the second light hole K2 corresponding to the position of the first light hole K1 is formed on the substrate 00, it is equivalent to further reducing the number of film layers for the light to be transmitted from the first transparent light guide unit 40 to the photosensitive element 300 during the photosensitive phase, effectively reducing the light loss when light is transmitted to the photosensitive element 300, facilitating increasing the light sensitivity of the photosensitive element 300, and improving the photosensitive performance of the display panel.

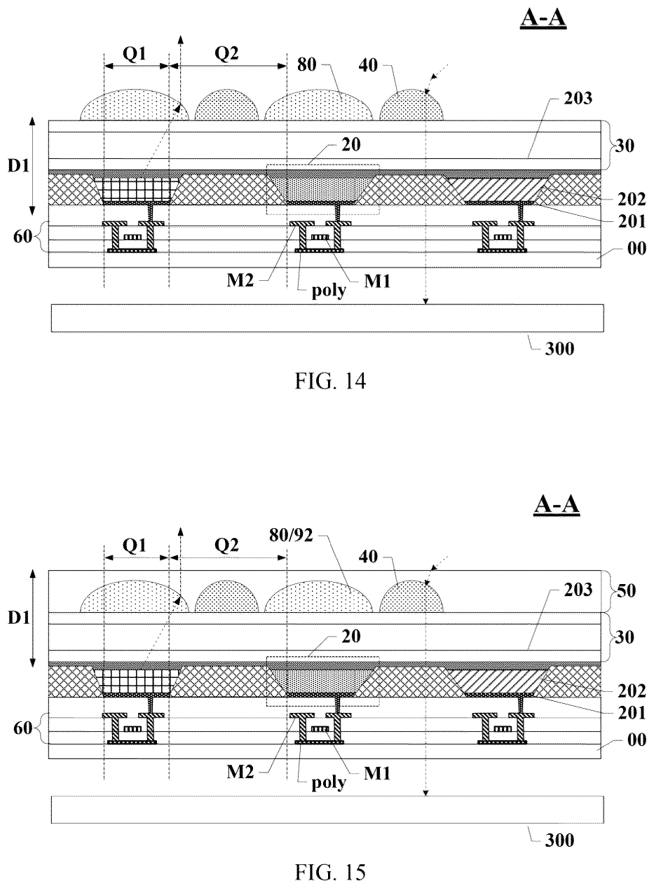

FIG. 14 shows another AA cross-sectional view of the display panel in FIG. 1. Please refer to FIG. 1 and FIG. 14. In some embodiments, the display panel also includes a second transparent light guide unit 80 located at least in the first display area A1. The second transparent light guide unit 80 is located on the side of the packaging layer 30 away from the substrate 00. Along the first direction D1, the second transparent light guide unit 80 overlaps the light emitting element 20. The second transparent light guide unit 80 is used to guide the light emitted by the light emitting element 20 to a light-exiting surface of the display panel.

Specifically, embodiments of the present disclosure show a scheme of simultaneously disposing the first transparent light guide unit 40 and the second transparent light guide unit 80 in the first display area A1 of the display panel. The second transparent light guide unit 80 is disposed in the opening area Q1 and located directly above the light-emitting element 20. When a light emitted by the light-emitting element 20 is directed to the second transparent light guide unit 80, the second transparent light guide unit 80 can conduct the light emitted by the light-emitting element 20 to the light-exiting surface of the display panel, improving the effective utilization rate of the light emitted by the light-emitting element 20. Therefore, embodiments of the present disclosure use the first transparent light guide unit 40 to increase the light sensitivity of the photosensitive element 300 during the photosensitive phase, improving the overall photosensitive performance of the display panel. At the same time, through the second transparent light guide unit 80, effective utilization of the light emitted by the light emitting element 20 is increased, improving the overall light emission of the display panel during the display phase.

FIG. 15 shows another AA cross-sectional view of the display panel in FIG. 1. Please refer to FIG. 1 and FIG. 15. In some embodiments, the display panel also includes a flat layer 50. The flat layer 50 is located on the side of the first transparent light guide unit 40 away from the substrate 00, disposed in the first display area A1 and the second display area A2, and covering the first transparent light guide unit 40 and the second transparent light guide unit 80. A refractive index of the flat layer 50 is N1. A refractive index of the first transparent light guide unit 40 is N2. A refractive index of the packaging layer 30 in contact with the second transparent light guide unit 80 is N3. A refractive index of the second transparent light guide unit 80 is N4. N1<N2<N3<N4.

Specifically, embodiments of the present disclosure illustrate a scheme that when the first transparent light guide unit 40 and the second transparent light guide unit 80 are introduced into the display panel, the flat layer 50 is introduced on one side of the first transparent light guide unit 40 and the second transparent light guide unit 80 away from the substrate 00. The flat layer 50 covers the first transparent light guide unit 40 and the second transparent light guide unit 80. A flat surface is formed on the side of the first transparent light guide unit 40 and the second transparent light guide unit 80 away from the substrate 00. The present disclosure sets the refractive index N2 of the first transparent light guide unit 40 to be between the refractive index N1 of the flat layer 50 and the refractive index N3 of the packaging layer 30 in contact with the first transparent light guide unit 40 and the second transparent light guide unit 80. During the photosensitive phase, when an external large-viewing-angle light is transmitted from the flat layer 50 to the first transparent light guide unit 40 and the packaging layer 30, the refraction angle gradually decreases, and this portion of the light will be transmitted to the photosensitive element 300. This is equivalent to changing the optical path of a light that cannot be transmitted to the photosensitive element 300 in an original large-viewing-angle light. Thus, it can be smoothly transmitted to the photosensitive element 300, effectively increasing the amount of light transmitted to the photosensitive element 300, which is beneficial to improving the photosensitive performance of the display panel. In addition, by further defining the refractive index N4 of the second transparent light guide unit 80 to be greater than the refractive indices of the packaging layer 30 and the flat layer 50, a refraction angle becomes larger, when a light emitted by the light emitting element 20 is transmitted to the packaging layer 30, the second transparent light guide unit 80, and the flat layer 50. Thus, the second transparent light guide unit 80 plays a role in converging the light. The large-viewing-angle light emitted by the light-emitting element 20 is deflected in the direction of the front viewing angle after being transmitted by the second transparent light guide unit 80. This is beneficial to increasing the amount of light emitted from the light-emitting element 20 at the front viewing angle, which is beneficial to increasing the amount of light emitting from the first display area A1 at the front viewing angle, and thus is beneficial to increasing the brightness at the front viewing angle.

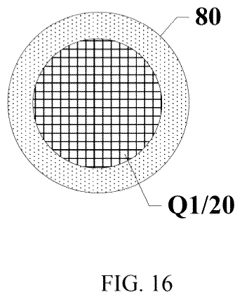

FIG. 16 shows a top view of the second transparent light guide unit 80 and its corresponding light emitting element 20. As shown in FIG. 16, in an optional implementation of the present invention, in the first display area A1, the second transparent light guide unit 80 is arranged in one-to-one correspondence with the light-emitting element 20. Along the first direction D1, the second transparent light guide unit 80 covers the light-emitting element 20, and the outline of the orthographic projection of the second transparent light guide unit 80 in the substrate 00 plane is located at the periphery of the outline of the orthographic projection of the light-emitting element 20 on the substrate 00 plane.

Specifically, when the second transparent light guide unit 80 is introduced in the first display area A1, one second transparent light guide unit 80 can be introduced directly above each light-emitting element 20 in the first display area A1. Thus, the second transparent light guide unit 80 increases the light emission of the corresponding light emitting element 20. In addition, embodiments of the present disclosure further define that the area of the orthographic projection of the second transparent light guide unit 80 on the substrate 00 plane is larger than the area of the orthographic projection of the light-emitting element 20 on the substrate 00 plane. The outline of the second transparent light guide unit 80 is located at the periphery of the outline of the light-emitting element 20. Thus, the large-viewing-angle light emitted by the light-emitting element 20 can also be directed to the second transparent light guide unit 80. Through the light guiding function of the second transparent light guide unit 80, the large-viewing-angle light can change the optical path to be conducted in a direction of the front viewing angle. Therefore, the light emission amount of the light-emitting element 20 at the front viewing angle is increased, which is beneficial to increasing the overall light emission amount of the first display area A1 at the front viewing angle.

As shown in FIG. 14 and FIG. 15 together with FIG. 1, in some embodiments, the second transparent light guide unit 80 includes a second microprism 92. A first cross-section of the second microprism 92 is semicircular, and the first cross-section is parallel to the first direction D1.

The second microlens 92 introduced in some embodiments is hemispherical and has a semicircular cross-section. When the light emitted by the light-emitting element 20 passes through the second microlens 92, a hemispherical second microlens 92 converges the light, facilitating converging the large-viewing-angle light emitted by the light-emitting element 20 to the front viewing angle. Thus, the brightness of the light emitting element 20 at the front viewing angle is enhanced. Optionally, a transmittance of the first display area A1 is higher than a transmittance of the second display area A2, the pixel density of the first display area A1 may be smaller than the pixel density of the second display area A2, or a corresponding relationship between the pixel circuit and the light-emitting elements 20 in the first display area A1 is one drive two or one drive many. Thus, a display brightness of the first display area A1 is lower than a display brightness of the second display area A2. When the second microlens is introduced into the first display area A1 in embodiments of the present disclosure, the brightness of the front viewing angle of the light-emitting element 20 in the first display area A1 is effectively improved, reducing a brightness difference between the first display area A1 and the second display area A2, and improving the uniformity of the overall display brightness between the first display area A1, and the second display area A2.

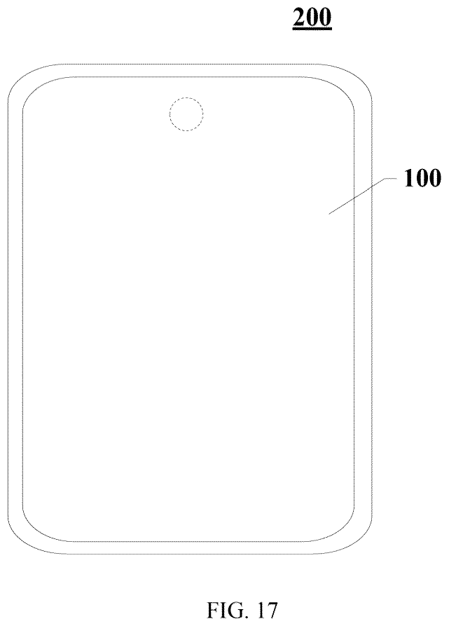

Based on the same idea, the present disclosure further provides a display device. FIG. 17 is a top view of a display device provided by embodiments of the present disclosure. A display device 200 includes the display panel 100 depicted in any of the above embodiments.

The display device 200 provided in embodiments of the present disclosure can be a touch screen, a mobile phone, a tablet computer, a notebook computer, an e-book, a television, or any other electronic devices with a display function. The display device 200 provided by embodiments of the present disclosure has advantages of the display panel 100 provided by embodiments of the present disclosure. For details, please refer to the specific description of the display module 100 in the above embodiments, which will not be described again.

It can be understood that FIG. 17 only illustrates one shape of the display device 200 by taking a rounded rectangular structure as an example. In some embodiments, the display device 200 can also be embodied in a rectangular, circular, elliptical shape, or any other feasible shapes, which is not specifically restricted by the present disclosure.

It can be seen from the above embodiments that the display panel and display device provided by the present disclosure at least achieve the following beneficial effects.

In the display panel and display device provided by the present disclosure, the first display area in the display area can be regarded as a photosensitive area corresponding to the photosensitive element. It is used to perform the display function during the display phase and to perform the photosensitive function during the photosensitive phase. The photosensitive element can be, for example, a camera. During the photosensitive phase, the first display area is used to capture images. The second display area in the display area can be regarded as a conventional display area in the display panel. During the display phase, the first display area and the second display area jointly exert the function of screen display, thereby realizing a full-screen display of a display product. It is beneficial to improving the screen-to-body ratio of the display product. A light-emitting element is provided in both the first display area and the second display area. When power is supplied to the anode and cathode appropriately, the light-emitting layer of the light-emitting element will emit light to realize the display function. A packaging layer is provided on the side of the light-emitting element facing away from the substrate, and used to package the light-emitting element and improve light-emitting reliability. The present disclosure at least introduces a first transparent light guide unit into the first display area. The first transparent light guide unit is located in the non-opening area. During the photosensitive phase, the first transparent light guide unit can conduct external light to the photosensitive element. Compared with products without the first transparent light guide unit, the light sensitivity of the photosensitive element during the photosensitive stage is effectively increased, which is beneficial to improving the photosensitive performance of the display panel and the display device.

Although some embodiments of the present disclosure have been described in detail by examples, those persons of ordinary skill in the art will understand that the above examples are for illustration only and are not intended to limit the scope of the invention. Those persons of ordinary skill in the art will understand that the above embodiments can be modified without departing from the scope and spirit of the present disclosure. The scope of the present disclosure is defined by the appended claims.

What is claimed is:

1. A display panel, comprising:
a display area, wherein
the display area comprises a first display area and a second display area at least partially surrounding the first display area; the first display area is configured with a photosensitive element; and at least one of the first display area and the second display area comprises an opening area and a non-opening area located between adjacent opening areas;
a substrate;
a light-emitting element, located over one side of the substrate and in the display area, wherein
the light-emitting element comprises an anode, a light-emitting layer, and a cathode; along a first direction, the light-emitting layer is located between the anode and the cathode; the light-emitting layer is located at least in the opening area; and the first direction is perpendicular to a plane of the substrate;
a packaging layer, located over one side of the light-emitting element away from the substrate; and
a first transparent light guide unit, located in the first display area and over one side of the packaging layer away from the substrate, wherein
the first transparent light guide unit is only located in the non-opening area; the display panel comprises a photosensitive phase; and during the photosensitive phase, the first transparent light guide unit is used to guide external light to the photosensitive element.

2. The display panel according to claim 1, further comprising a flat layer, located over one side of the first transparent light guide unit away from the substrate, located in the first display area and the second display area, and covering the first transparent light guide unit, wherein
a refractive index of the flat layer is N1;
a refractive index of the first transparent light guide unit is N2;
a refractive index of the packaging layer contacting the first transparent light guide unit is N3; and
N1<N2<N3.

3. The display panel according to claim 1, wherein
the first transparent light guide unit comprises a first microprism;
the first microprism has a first cross-section that is either semicircular or trapezoidal; and
the first cross-section is parallel to the first direction.

4. The display panel according to claim 1, further comprising an array layer, wherein
the array layer is located between the substrate and the light-emitting element;
the array layer comprises a metal structure; and
along the first direction, the first transparent light guide unit does not overlap with the metal structure.

5. The display panel according to claim 1, wherein
the first display area comprises a first area and a second area surrounding the first area; the second area is located between the first area and the second display area; the first transparent light guide unit comprises a first light guide unit located in the first area and a second light guide unit located in the second area; and
along the first direction, a projected area of one first light guide unit on the substrate plane is S1; a projected area of one second light guide unit on the substrate plane is S2; and S1>S2.

6. The display panel according to claim 1, wherein
the first display area comprises a first area and a second area surrounding the first area; the second area is located between the first area and the second display area; the first transparent light guide unit comprises a first light guide unit located in the first area and a second light guide unit located in the second area; and
an arrangement density of the second light guide unit is greater than an arrangement density of the first light guide unit.

7. The display panel according to claim 1, wherein
a first gap is located between an orthogonal projection of the first transparent light guide unit on the plane of the substrate and an adjacent opening area of the first transparent light guide unit;
a minimal width of the first gap is D0, and D0=a×tan θ; ‘a’ is a distance between a surface of the first transparent light guide unit facing the substrate and a surface of the light-emitting layer facing the anode along the first direction;
an edge of the opening area facing an adjacent first transparent light guide unit of the opening area is a first edge; an edge of the first transparent light guide unit facing an adjacent opening area of the first transparent light guide unit is a second edge; and
a line connecting the first edge and the second edge is a first line segment; θ is an acute angle between a line of the first line segment and the plane of substrate, and 15°≤θ≤30°.

8. The display panel according to claim 1, wherein
the packaging layer comprises a plurality of grooves; a groove of the plurality of grooves is located in the non-opening area; and the first transparent light guide unit is located in the groove.

9. The display panel according to claim 8, wherein
the packaging layer comprises a first inorganic layer, an organic layer, and a second inorganic layer; along the first direction, the organic layer is located between the first inorganic layer and the second inorganic layer; the organic layer is located at least in the opening area; and the organic layer does not overlap with the groove.

10. The display panel according to claim 1, further comprising
an array layer, located between the substrate and the light-emitting element; and
in the first display area, a total thickness of the array layer that overlaps with the first transparent light guide unit along the first direction is smaller than a total thickness of the array layer in the opening area.

11. The display panel according to claim 10, wherein
the array layer comprises a first light hole located in the non-opening area; along the first direction, the first light hole penetrates at least a portion of the array layer; and the first light hole overlaps with the first transparent light guide unit.

12. The display panel according to claim 1, wherein
the substrate comprises a second light hole located in the non-opening area; along the first direction, the second light hole penetrates through the substrate and the second light hole overlaps with the first transparent light guide unit; and the photosensitive element is located over one side of the substrate away from the light-emitting element.

13. The display panel according to claim 1, further comprises a second transparent light guide unit at least located in the first display area, wherein
the second transparent light guide unit is located over the side of the packaging layer away from the substrate; along the first direction, the second transparent light guide unit overlaps with the light-emitting element; and the second transparent light guide unit is used to guide a light emitted by the light-emitting element to a light-exiting surface of the display panel.

14. The display panel according to claim 13, further comprising a flat layer located over one side of the first transparent light guide unit away from the substrate, located in the first display area and the second display area, and covering both the first transparent light guide unit and the second transparent light guide unit, wherein
a refractive index of the flat layer is N1; a refractive index of the first transparent light guide unit is N2; a refractive index of the packaging layer contacting the second transparent light guide unit is N3; a refractive index of the second transparent light guide unit is N4; and N1<N2<N3<N4.

15. The display panel according to claim 13, wherein
in the first display area, the second transparent light guide unit is arranged in a one-to-one correspondence with the light-emitting element; along the first direction, the second transparent light guide unit covers the light-emitting element; and an outline of an orthographic projection of the second transparent light guide unit on the plane of the substrate is located on a periphery of an outline of an orthographic projection of the light-emitting element on the plane of the substrate.

16. The display panel according to claim 13, wherein
the second transparent light guide unit comprises a second microprism; a first cross-section of the second microprism is semi-circular; and the first cross-section is parallel to the first direction.

17. A display device, comprising:
a display panel, comprising:
a display area, wherein
the display area comprises a first display area and a second display area at least partially surrounding the first display area; the first display area is configured with a photosensitive element; and at least one of the first display area and the second display area comprises an opening area and a non-opening area located between adjacent opening areas;
a substrate;
a light-emitting element, located over one side of the substrate and in the display area, wherein
the light-emitting element comprises an anode, a light-emitting layer, and a cathode; along a first direction, the light-emitting layer is located between the anode and the cathode; the light-emitting layer is located at least in the opening area; and the first direction is perpendicular to a plane of the substrate;
a packaging layer, located over one side of the light-emitting element away from the substrate; and
a first transparent light guide unit, located in the first display area and over one side of the packaging layer away from the substrate, wherein
the first transparent light guide unit is only located in the non-opening area; the display panel comprises a photosensitive phase; and during the photosensitive phase, the first transparent light guide unit is used to guide external light to the photosensitive element.
